(19) United States
(12) Patent Application Publication
(10) Pub. No.: US 2007/0128810 A1
(43) Pub. Date: Jun. 7, 2007

(54) Ultra high voltage MOS transistor device and method of making the same

(76) Inventor: Ching-Hung Kao, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 11/164,828

(22) Filed: Dec. 7, 2005

(51) Int. Cl. H01L 21/336

(52) U.S. Cl. 438/286

(57) ABSTRACT

An ultra high voltage MOS transistor device includes a gate laterally extending onto a first dielectric layer having a void under the gate edge, and a second dielectric layer covering the gate and the first dielectric layer while retaining the void. The first dielectric layer may be in a form of a field oxide layer or a shallow trench isolation, and a thickness increasing dielectric layer may be further stacked on the field oxide layer or the shallow trench isolation. The thickness increasing dielectric layer may comprise a low dielectric constant material or the shallow trench isolation may be filled with porous oxide material, and then the first dielectric layer may not have the void. In the ultra high voltage MOS transistor device, the vertical electric field occurring nearby the gate edge is relatively low.

### BACKGROUND OF THE INVENTION

1. Field of the Invention

The present invention relates to ultra high voltage semiconductor devices and, more particularly, to an ultra high voltage MOS transistor device having a relatively low vertical electric field at the gate edge.

2. Description of the Prior Art

High-voltage metal-oxide-semiconductor (HVMOS) transistors are widely used in many electrical devices, such as CPU power supplies, power management systems, AC/DC converters, etc.

FIG. 1 schematically illustrates a cross-sectional view of a conventional ultra high voltage NMOS transistor device. The conventional ultra high voltage NMOS transistor device 1 is fabricated on an active area of a semiconductor substrate 10 such as a P type silicon substrate. The active area is isolated by a peripheral field oxide layer 44. Generally, the conventional ultra high voltage NMOS transistor device 1 comprises a source 14, a gate 50 and a drain 24. The source 14 is a heavily N doped region bordering upon a heavily P doped region 16, both of which are formed within a P well 12. The distance between the drain 24 and the source 14 may be a few micrometers. The drain 24 is a heavily N doped drain and is formed within an N well 22 that is formed within a deep N well 30, forming a triple-well structure.

As shown in FIG. 1, a gate dielectric layer 46 is formed on the source 14. The gate 50 is formed on the gate dielectric layer 46 and laterally extends over a field oxide layer 42. The field oxide layer 42 is formed between the source 14 and drain 24 using a local oxidation of silicon (LOCOS) technique. To prevent breakdown of the MOS device operated at a high voltage ranging from hundreds to thousands volts, the field oxide layer 42 having a thickness t of at least 10,000 angstroms is required.

It is evident that when the thickness t of the field oxide layer 42 is greater than 10,000 angstroms, the high vertical electric field caused by the gate edge 52 can be significantly reduced. However, it is problematic to form such thick field oxide layer 42 because it takes extra time. The wafers will have to stay in the furnace longer, and this means reduced throughput. Furthermore, a thicker field oxide layer also leads to a problem of step height during the subsequent fabrication process.

Therefore, there is a need for an improved high voltage MOS structure and the manufacturing method to reduce the vertical electric field effect.

### SUMMARY OF THE INVENTION

It is an object of the present invention to provide an improved ultra high voltage MOS transistor device, which reduces the vertical electric field caused by the gate edge.

According to the present invention, an ultra high voltage metal-oxide-semiconductor (MOS) transistor device is disclosed. The ultra high voltage MOS transistor device includes a semiconductor substrate; at least one doping region in the semiconductor substrate; a gate on the semiconductor substrate; a first dielectric layer between the gate and the doping region for isolation, wherein the gate laterally extends onto the first dielectric layer and the first dielectric layer has at least one void under an edge of the gate; and a second dielectric layer disposed on the gate, the doping region, and the first dielectric layer, wherein the void is retained.

In one embodiment according to the present invention, the ultra high voltage MOS transistor device includes a substrate of a first conductivity type; a source doping region of a second conductivity type formed in the substrate; a first doping region of the first conductivity type formed in the substrate and bordering upon the source doping region; a first ion well of the first conductivity type encompassing the source doping region and the first doping region; a gate dielectric layer formed on the source doping region and on the first ion well; a first dielectric layer connected with the gate dielectric layer and formed on a semiconductor region; a drain doping region of the second conductivity type formed at one side of the field dielectric layer and being spaced apart from the source doping region; a second ion well of the second conductivity type encompassing the drain doping region; a gate disposed on the gate dielectric layer and laterally extending onto the first dielectric layer, wherein the first dielectric layer comprises a void under an edge of the gate; and a second dielectric layer disposed on the gate, the gate dielectric layer, and the first dielectric layer, wherein the void is retained.

In another embodiment according to the present invention, the ultra high voltage MOS transistor device is as described above except that the first dielectric layer comprises a porous oxide material and may be without the void.

In another embodiment according to the present invention, the ultra high voltage MOS transistor device is as described above except that the first dielectric layer comprises a low dielectric constant (low k) material layer and a field oxide layer and may be without the void.

From one aspect of the present invention, the method of manufacturing an ultra high voltage MOS transistor device includes the steps as follows. First, a substrate of a first conductivity type is provided. A first ion well of the first conductivity type and a second ion well of the second conductivity type are formed, respectively. A first doping region of the first conductivity type is formed in the first ion well. A source doping region of a second conductivity type and a drain doping region of the second conductivity type are formed in the first ion well and the second ion well, respectively. The source doping region borders upon the first doping region, such that the first ion well encompasses the source doping region and the first doping region. Next, a gate dielectric layer is formed on the source doping region and on the first ion well. A first dielectric layer is formed on a semiconductor region and connected with the gate dielectric layer. The drain doping region is spaced apart from the source doping region with the first dielectric layer therebetween. Then, a gate is formed on the gate dielectric layer and laterally extends onto the first dielectric layer. A part of the first dielectric layer under an edge of the gate is removed to form an opening. Finally, a second dielectric layer is disposed on the gate, the gate dielectric layer, and the first dielectric layer, such that a void is formed in situ of the opening.

In yet still another embodiment according to the present invention, the method of manufacturing an ultra high voltage MOS transistor device comprises the steps as follows. First, a substrate of a first conductivity type is provided. A first ion well of the first conductivity type and a second ion well of the second conductivity type are formed, respectively. A first doping region of the first conductivity type is formed in the first ion well. A source doping region of a second conductivity type and a drain doping region of the second conductivity type are formed in the first ion well and the second ion well, respectively. The source doping region borders upon the first doping region, such that the first ion well encompasses the source doping region and the first doping region. Next, a gate dielectric layer is formed on the source doping region and on the first ion well. A field oxide layer is formed on a semiconductor region. A low dielectric constant material layer is formed on the field oxide layer. The drain doping region is spaced apart from the source doping region with the field oxide layer therebetween. Then, a gate is formed on the gate dielectric layer and laterally extends to the first dielectric layer. Finally, a dielectric layer is disposed on the gate, the gate dielectric layer, and the low dielectric constant material layer.

In still another embodiment according to the present invention, the method of manufacturing an ultra high voltage MOS transistor device comprises the steps as follows. First, a substrate of a first conductivity type is provided. A first ion well of the first conductivity type and a second ion well of the second conductivity type are formed, respectively. A first doping region of the first conductivity type is formed in the first ion well. A source doping region of a second conductivity type and a drain doping region of the second conductivity type are formed in the first ion well and the second ion well, respectively. The source doping region borders upon the first doping region, such that the first ion well encompasses the source doping region and the first doping region. Next, a gate dielectric layer is formed on the source doping region and on the first ion well. A shallow trench isolation region is formed on a semiconductor region and is connected to the gate dielectric layer. The shallow trench isolation region is filled with a porous oxide material. The drain doping region is spaced apart from the source doping region with the shallow trench isolation region therebetween. Then, a gate is formed on the gate dielectric layer and laterally extends to the first dielectric layer. Finally, a dielectric layer is disposed on the gate, the gate dielectric layer, and the shallow trench isolation material.

According to the present invention, the ultra high voltage MOS transistor device comprises a void under the gate edge (also called field plate edge) to reduce the electric field. Alternatively, the dielectric layer under the gate edge is formed to comprise a low dielectric constant material for reducing the electric field. Thus, a very thick oxide layer is not necessarily used under the gate edge for reducing the electric field. Therefore, the problem arising from the difficulty to form the very thick oxide layer or the step height will not occur.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 schematically illustrates a cross-sectional view of a prior art ultra high voltage NMOS transistor device.

FIG. 2 is a schematic cross-sectional diagram illustrating an ultra high voltage NMOS transistor device according to the present invention.

FIG. 3 is a schematic cross-sectional diagram illustrating an ultra high voltage NMOS transistor device of another embodiment according to the present invention.

FIG. 4 is a schematic cross-sectional diagram illustrating an ultra high voltage NMOS transistor device of another embodiment according to the present invention.

FIG. 5 is a schematic cross-sectional diagram illustrating an ultra high voltage NMOS transistor device of still another embodiment according to the present invention.

FIG. 6 is a schematic cross-sectional diagram illustrating an ultra high voltage NMOS transistor device of yet still another embodiment according to the present invention.

FIG. 7 is a schematic cross-sectional diagram illustrating an ultra high voltage NMOS transistor device of yet still another embodiment according to the present invention.

FIGS. 8 and 9 are schematic cross-sectional diagrams illustrating a manufacturing process of ultra high voltage NMOS transistor device according to the present invention.

FIG. 10 is a schematic cross-sectional diagram illustrating an ultra high voltage NMOS transistor device according to the present invention.

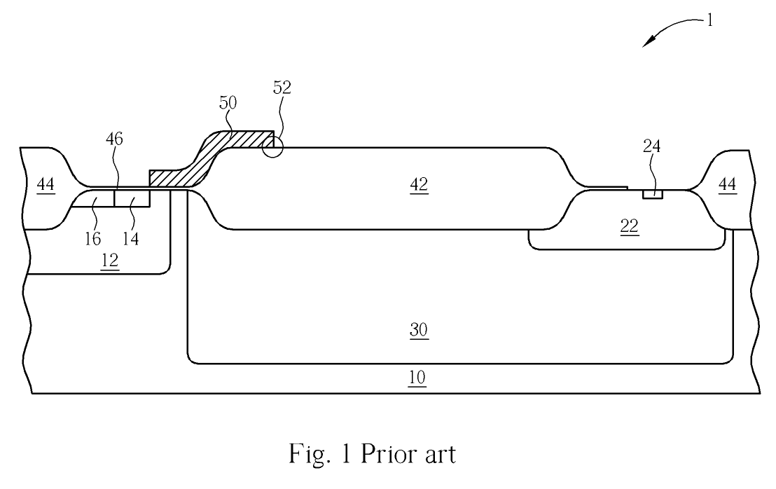

### DETAILED DESCRIPTION

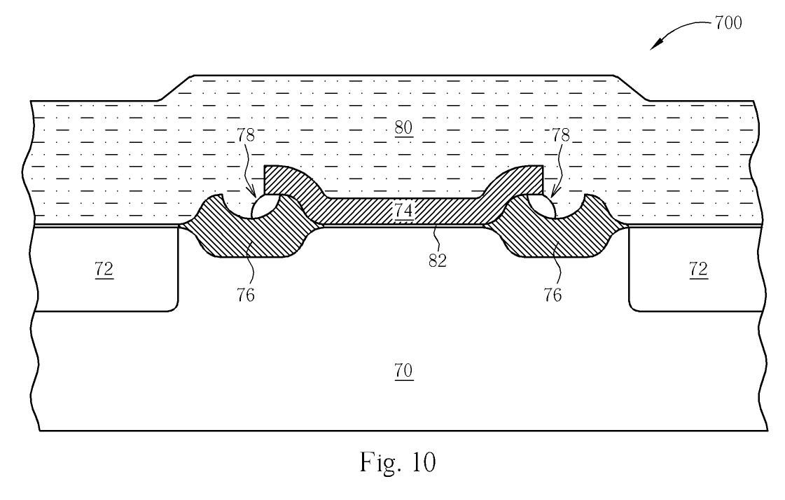

FIG. 10 is a schematic cross-sectional diagram illustrating an ultra high voltage MOS transistor device according to the present invention. The ultra high voltage NMOS transistor device 700 is formed on a semiconductor substrate 70 and includes at least one doping region, such as, but not limited to, a source/drain 72, and a gate 74. The gate 74 and the source/drain 72 are isolated from each other by a dielectric layer 76 therebetween. The gate 74 laterally extends over the dielectric layer 76. The dielectric layer 76 has a void 78 under an edge of the gate 74. Another dielectric layer 80 covers the source/drain 72, the gate 74, and the dielectric layer 76, while the void 78 is retained.

The term “at least one doping region” means there may be one or more doping regions. For example, one is a source and another is a drain positioned at two ends of the gate, respectively. A dielectric layer is disposed between the gate and the source and the drain for isolation. There is a void in the dielectric layer under the edge of any end of the gate. For example, there is a void in the dielectric layer under the edge of an end of the gate toward the drain; there is a void in the dielectric layer under the edge of an end of the gate toward the source, or both.

The ultra high voltage NMOS transistor device 700 may further comprise a gate dielectric layer 82 between a gate 74 and a semiconductor substrate 70. The dielectric layer 76 may be for example in a form of a field oxide layer or a shallow trench isolation region. Another dielectric layer for thickness may be further stacked on the field oxide layer or the shallow trench isolation region. In such case, the void may be only positioned at the dielectric layer, or at both the dielectric layer and the field oxide or the shallow trench isolation. The void may be further filled with a low dielectric constant material. Such dielectric layer structure having a void may be replaced with a shallow trench isolation region filled with a porous oxide material or a stacked structure of a low dielectric constant layer and a field oxide layer, without a void.

The present invention may be applied to, but not limited to, a vertical double-diffusion metal-oxide-semiconductor (VDMOS), an insulated gate bipolar transistor (IGBT), and a lateral-diffusion metal-oxide-semiconductor (LDMOS) for manufacturing high voltage devices in the chips. The present invention may be also applicable to double diffuse drain (DDD) structures.

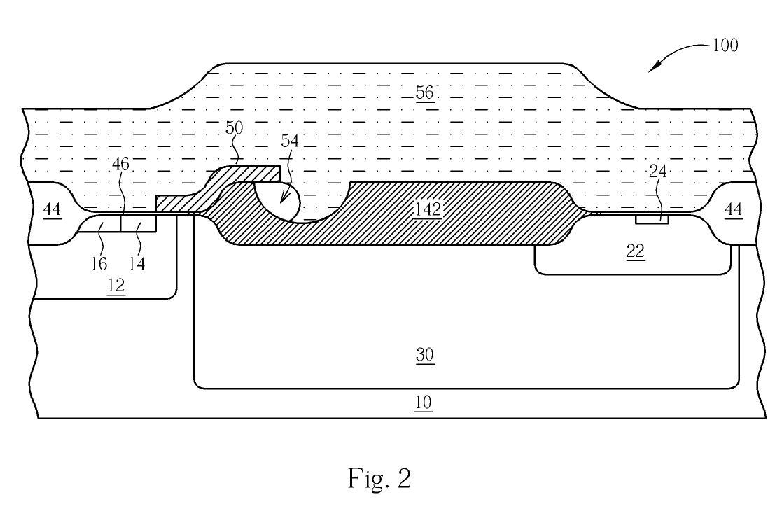

The present invention is more described in detail by the embodiments set forth as follows. Please refer to FIG. 2. FIG. 2 is a schematic cross-sectional diagram illustrating an ultra high voltage NMOS transistor device in accordance with one preferred embodiment of this invention. It is understood that the charge properties shown in figures are exemplary, and suitable modification of the polarities can be made to form an ultra high voltage PMOS transistor device.

According to the preferred embodiment, the ultra high NMOS transistor device 100 is formed on an active area of a semiconductor substrate 10 such as a P type silicon substrate. The active area is defined and isolated with a peripheral field oxide layer 44. Likewise, the ultra high NMOS transistor device 100 comprises a source 14, a gate 50, and a drain 24. The source 14 is heavily N doped and borders upon a heavily P doped region 16, both of which are formed within a P well 12. The distance between the drain 24 and the source 14 may be a few micrometers or more. The drain 24 is heavily N doped and formed within an N well 22, that may be further formed within a deep N well 30 to form a triple gradient well structure. The gate 50 may be made of polysilicon or metals.

In one embodiment according to the present invention, a gate dielectric layer, such as the gate oxide layer 46, is formed on the source 14. The gate 50 is formed on the gate oxide layer 46 and laterally extends over a dielectric layer, such as a field oxide layer 142, disposed on a semiconductor region. There is a void 54 at the field oxide layer 142 under the edge of the gate 50. Furthermore, a plurality of floating field plates (not shown) may be formed on the field oxide layer 142 to disturb the lateral electric field. The field oxide layer 142 is formed between the source 14 and drain 24 using conventional local oxidation of silicon (LOCOS) technique. A dielectric layer 56, such as an oxide layer, is a formed as an upper layer to cover the gate 50, the gate oxide layer 46, and the field oxide layer 142, while the void 54 is retained as a hole and not filled up with the dielectric material used for the dielectric layer 56. One characterization of the present invention is that there is a void under the edge of the gate. The void is not particularly restricted to any size. The void serves to reduce the vertical electric field at the gate edge, and in turn, the thickness of the dielectric layer (the field oxide layer 142, for example) can be correspondingly reduced.

In accordance with the paper entitled with “Optimization of RESURF LDMOS Transistors: An Analytical Approach (IEEE Transactions on Electron Devices, Vol. 37, No. 3, March 1990) by Zahir Parpia et al., the breakdown voltage of a device, BVc, can be expressed as
BV_{c}=φ_{cy}+(tₒₓ/ε₀εₒₓ)×(2ε₀εₛᵢqN_{D}φ_{cy})^{1/2}

where

BV_{c} is a breakdown voltage,

φ_{cy} is the total voltage drop across the oxide beneath the gate electrode,

tₒₓ is the thickness of the field oxide layer,

ε₀ is the permittivity of free space,

εₛᵢ and εₒₓ are the relative dielectric permittivities of silicon and silicon dioxide,

q is the charge, and

N_{D} is the concentration of dopant impurities.

In view of the equation above, it is known that the breakdown voltage increases as the εₒₓ decreases. According to the present invention, a MOS structure is formed to have a void positioned at the dielectric layer under the edge of the gate, such that an almost smallest εₒₓ can be obtained. Therefore, the thickness of the oxide layer used in the ultra high voltage MOS structure can be correspondingly reduced, and the step height is thus decreased.

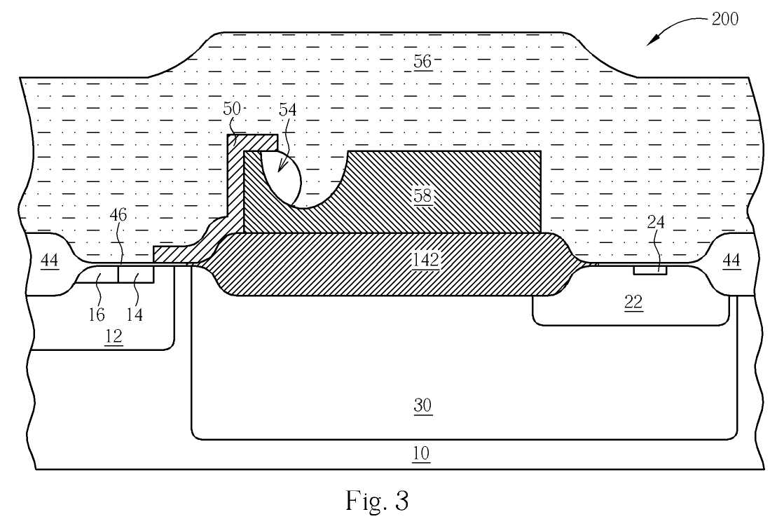

Referring to FIG. 3, an ultra high voltage NMOS transistor device 200 according to another preferred embodiment of this invention is illustrated. In the ultra high voltage NMOS transistor device 200, the dielectric layer under the gate 50 may further comprise, in addition to the field oxide layer 142, a thick dielectric layer, such as a thick oxide layer 58, on the field oxide layer 142 to increase the thickness. According to one characterization of the present invention, the void 54 is positioned at the thick oxide layer 58 under the edge of the gate 50. By doing this, the gate 50 is elevated and the dielectric constant under the edge of the gate is relatively reduced, thereby the problem of the high vertical electric field caused by the gate edge will be solved and the thickness of the oxide layer 58 may be relatively not too thick.

It should be also noted that the void under the edge of the gate 50 may be formed at both of the thick oxide layer and the field oxide layer together (not shown).

Additionally, based on the theory that the breakdown voltage increases as the εₒₓ decreases, the dielectric layer under the edge of the gate in the ultra high voltage MOS of the present invention may comprise a field oxide layer and a low dielectric constant material layer (not shown). In such case, the reduction of the vertical electric field is achieved without the formation of a void under the edge of the gate.

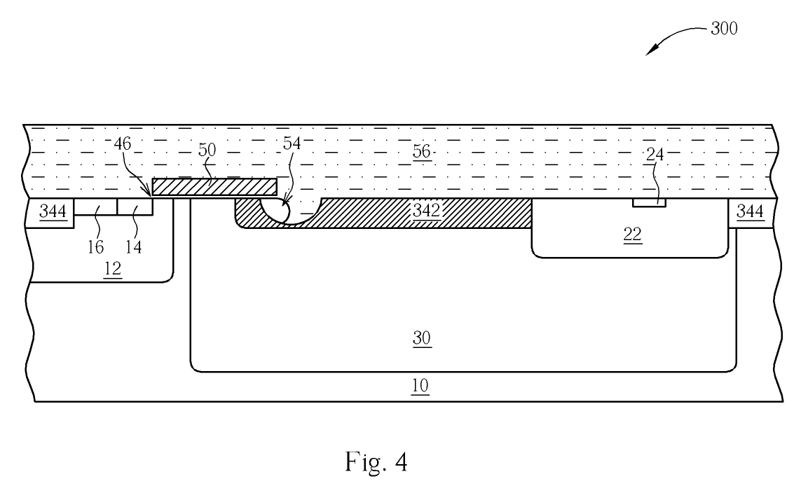

Referring to FIG. 4, an ultra high voltage NMOS transistor device 300 according to another preferred embodiment of the present invention is illustrated. The difference between the ultra high voltage NMOS transistor device 300 and the ultra high voltage NMOS transistor device 100 shown in FIG. 2 is that the dielectric layer in the ultra high voltage NMOS transistor device 300 comprises a shallow trench isolation region 342. A void 54 is also formed under the edge of the gate 50. The ultra high voltage NMOS transistor device is isolated by the shallow trench isolation region 344.

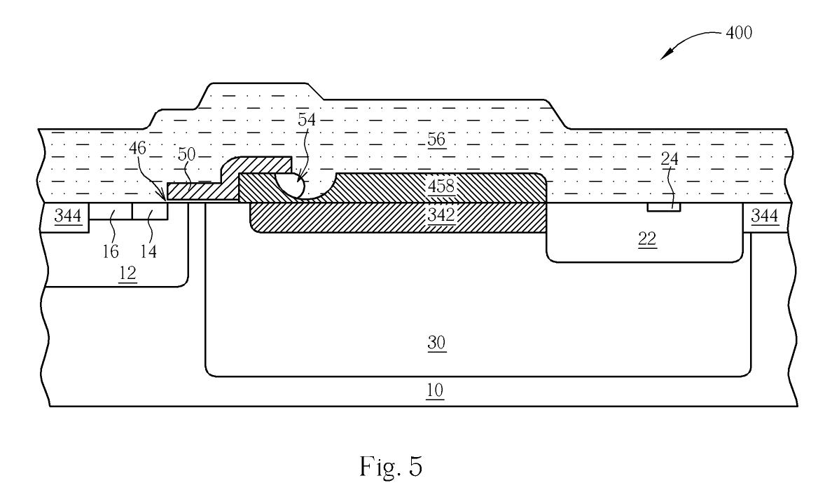

Referring to FIG. 5, an ultra high voltage NMOS transistor device 400 according to still another preferred embodiment of this invention is illustrated. The difference between the ultra high voltage NMOS transistor device 400 and the ultra high voltage NMOS transistor device 300 shown in FIG. 4 is that the dielectric layer In the ultra high voltage NMOS transistor device 400 comprises a shallow trench isolation region 342 and a thick dielectric layer, such as an oxide layer 458, on the shallow trench isolation region 342. A void 54 is also formed at the oxide layer 458 under the edge of the gate 50.

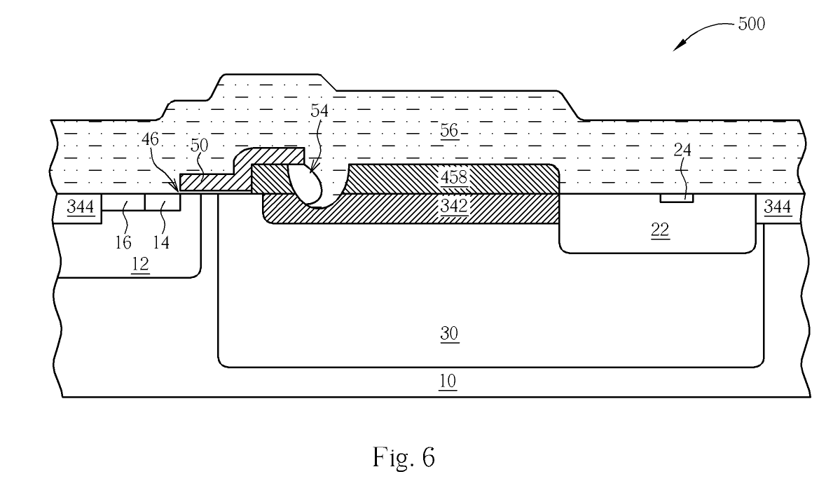

Referring to FIG. 6, an ultra high voltage NMOS transistor device 500 according to yet still another preferred embodiment of this invention is illustrated. The difference between the ultra high voltage NMOS transistor device 500 and the ultra high voltage NMOS transistor device 400 shown in FIG. 5 is that the void 54 under the edge of the gate 50 in the ultra high voltage NMOS transistor device 500 is formed at both of the shallow trench isolation region 342 and the oxide layer 458.

Such void formed in the embodiments of the ultra high voltage NMOS transistor device according to the present invention describe above may be further filled with a low dielectric constant material, and the effect of reducing the vertical electric field at the gate edge may also be achieved.

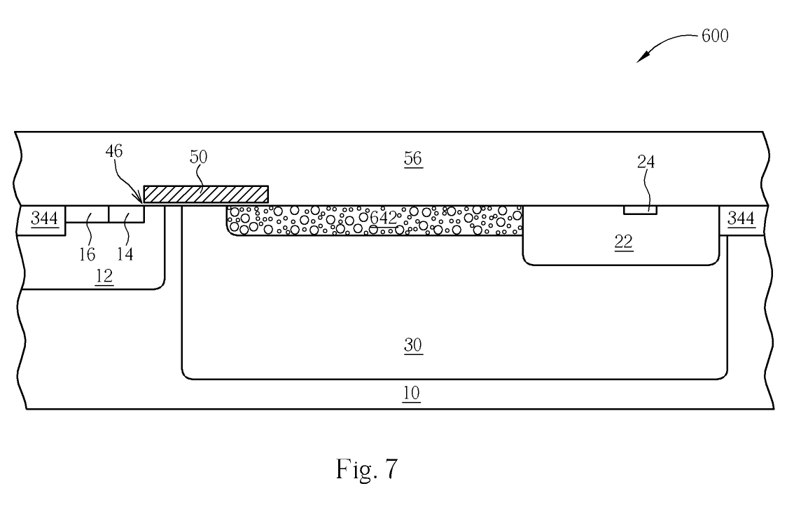

Referring to FIG. 7, an ultra high voltage NMOS transistor device 600 according to still another preferred embodiment of this invention is illustrated. The difference between the ultra high voltage NMOS transistor device 600 and the ultra high voltage NMOS transistor device 300 shown in FIG. 4 is that the dielectric layer in the ultra high voltage NMOS transistor device 600 comprises the shallow trench isolation region 642 filled with a porous oxide material to connect with the gate dielectric layer, while being without a void like the void 54.

The ultra high voltage NMOS transistor devices describe above are certain embodiments of the present invention. Furthermore, in the situation that the ultra high voltage NMOS transistor device comprises a deep N well (such as the deep N well 30), the deep N well may be replaced with an N type epitaxial silicon layer, such that the P well (such as the P well 12) and the N well (such as the N well 22) are formed in the N type epitaxial silicon layer.

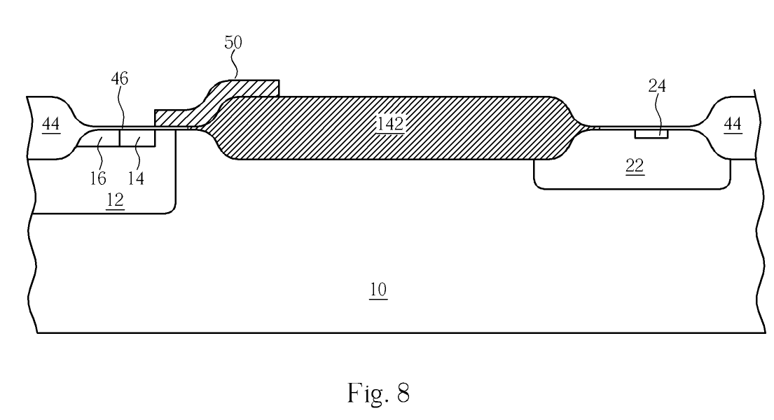

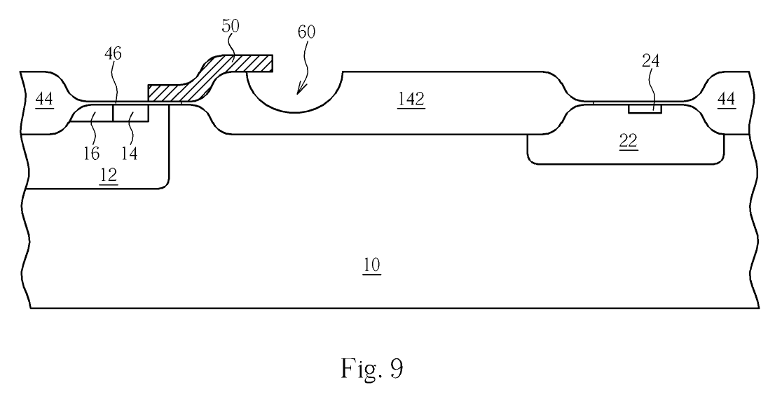

The ultra high voltage MOS transistor device may be manufactured using the method describe hereinafter. Please refer to FIGS. 8 and 9. As shown in FIG. 8, first, a substrate 10 is provided, for example, a semiconductor substrate of a certain type of conductivity, such as a P type or an N type silicon substrate. Two regions of the substrate 10 are incorporated with different conductivity type of ions, forming an ion well 12 and an ion well 22, respectively. Next, a doping region 16 with higher doping concentration is formed in the ion well 12, and a source doping region 14 and a drain doping region 24 are formed in the ion wells 12 and 22. The source doping region 14 borders upon the doping region 16, such that the ion well 12 encompasses the source doping region 14 and the doping region 16.

Subsequently, a layer of dielectric material, such as oxide, is deposited on the surface of the source doping region 14 and the ion well 12 to form a gate dielectric layer 46. Then, a dielectric layer 142 is formed on a semiconductor region to connect with the gate dielectric layer. The dielectric layer may be formed as a LOCUS structure or a shallow trench isolation region structure. For example, FIG. 8 shows a field oxide layer 142 formed as a LOCUS structure. Then, a gate 50 is formed on the gate dielectric layer 46 to laterally extend onto the field oxide 142. Such resulting semi-finished structure may be fabricated using a conventional technique. The present invention features in the following step of removing a part of the field oxide layer 142 around the place under the edge of the gate 50 to form a void. As shown in FIG. 9, the opening 60 is the result for removing a part the field oxide layer 142. The process of removal is not particularly limited as long as the removal can be achieved. For example, an isotropic etching technique, such as a wet etching or the like, may be used. An undercut under the edge of the gate can be formed using the isotropic etching technique. Finally, a deposition process is performed to cover an oxide layer on the substrate, that is, on the gate, gate dielectric layer, and field oxide layer. Due to the undercut structure formed, a void can be retained under the edge of the gate after the deposition process.

In addition to a LOCUS or a shallow trench isolation region, the dielectric layer may further comprise a thick dielectric layer, such as a thick oxide layer, on the formed LOCUS or shallow trench isolation region. The thick oxide layer may be formed by a CVD process, or by firstly depositing a doped polysilicon layer over the field oxide layer 142 followed by thermally oxidizing the doped polysilicon layer. There is no particular limitation for the void to be formed at the thick dielectric layer, or at both of the thick dielectric layer and the field oxide layer or the shallow trench isolation region. In addition, the void may be filled up with a low dielectric constant material.

In another embodiment according to the present invention, the method of manufacturing an ultra high voltage MOS transistor device comprises the steps as follows. After a field oxide layer is formed on a semiconductor region as the embodiment described above, a low dielectric constant material layer is formed (such as, deposited) on the field oxide layer, followed by forming a gate on the gate dielectric layer, and the gate is allowed to extend onto the low dielectric constant material layer. Finally, a dielectric layer is formed on the gate, gate dielectric layer, and the low dielectric constant material layer. In such embodiment of the present invention, the vertical electric field at the gate edge can be reduced by the formation of the low dielectric constant material layer under the edge of the gate, such that it is not necessary to form the void.

In another embodiment according to the present invention, the method of manufacturing an ultra high voltage MOS transistor device comprises the steps as follows. After the gate dielectric layer is formed on the source doping region and the ion well, as the embodiment described above, a shallow trench isolation region is formed to replace the formation of the field oxide layer. The shallow trench isolation region is formed through filling a porous oxide material in the shallow trench using a deposition process. Next, a gate is formed on the gate dielectric layer, and the gate is allowed to extend onto the shallow trench isolation region. Finally, a dielectric layer is formed on the gate, gate dielectric layer, and the low dielectric constant material layer, accomplishing the manufacturing of the ultra high MOS transistor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An ultra high voltage metal-oxide-semiconductor (MOS) transistor device, comprising:
a substrate of a first conductivity type;
a source doping region of a second conductivity type formed in the substrate;
a first doping region of the first conductivity type formed in the substrate and bordering upon the source doping region;
a first ion well of the first conductivity type encompassing the source doping region and the first doping region;
a gate dielectric layer formed on the source doping region and on the first ion well;
a first dielectric layer connected with the gate dielectric layer and formed on a semiconductor region;
a drain doping region of the second conductivity type formed at one side of the field dielectric layer and being spaced apart from the source doping region;
a second ion well of the second conductivity type encompassing the drain doping region;
a gate disposed on the gate dielectric layer and laterally extending onto the first dielectric layer, wherein the first dielectric layer comprises a void under an edge of the gate; and
a second dielectric layer disposed on the gate, the gate dielectric layer, and the first dielectric layer, wherein the void is retained.

2. The ultra high voltage MOS transistor device according to claim 1, wherein the first dielectric layer comprises a field oxide layer.

3. The ultra high voltage MOS transistor device according to claim 1, wherein the first dielectric layer comprises a field oxide layer connected with the gate dielectric layer and formed on the semiconductor region, and a third dielectric layer covering the field oxide layer, wherein the third dielectric layer comprises the void under the edge of the gate.

4. The ultra high voltage MOS transistor device according to claim 1, wherein the first dielectric layer comprises a field oxide layer connected with the gate dielectric layer and formed on the semiconductor region, and a third dielectric layer covering the field oxide layer, wherein the field oxide layer and the third dielectric layer together comprise the void under the edge of the gate.

5. The ultra high voltage MOS transistor device according to claim 1, wherein the void is filled with a low dielectric constant material.

6. The ultra high voltage MOS transistor device according to claim 1, wherein the first dielectric layer comprises a shallow trench isolation region.

7. The ultra high voltage MOS transistor device according to claim 1, wherein the first dielectric layer comprises a shallow trench isolation region connected with the gate dielectric layer and formed on the semiconductor region, and a third dielectric layer covering the shallow trench isolation region, wherein the third dielectric layer comprises the void under the edge of the gate.

8. The ultra high voltage MOS transistor device according to claim 1, wherein the first dielectric layer comprises a shallow trench isolation region connected with the gate dielectric layer and formed on the semiconductor region, and a third dielectric layer covering the shallow trench isolation region, wherein the shallow trench isolation region and the third dielectric layer together comprise the void under the edge of the gate.

9. The ultra high voltage MOS transistor device according to claim 1, further comprising a third ion well of the second conductivity type formed in the substrate underneath the first dielectric layer and encompassing the second ion well.

10. An ultra high voltage metal-oxide-semiconductor (MOS) transistor device, comprising:
a substrate of a first conductivity type;
a source doping region of a second conductivity type formed in the substrate;
a first doping region of the first conductivity type formed in the substrate and bordering upon the source doping region;
a first ion well of the first conductivity type encompassing the source doping region and the first doping region;
a gate dielectric layer formed on the source doping region and on the first ion well;
a field oxide layer connected with the gate dielectric layer and formed on a semiconductor region;
a low dielectric constant material layer covering the field oxide layer;
a drain doping region of the second conductivity type formed at one side of the field oxide layer and being spaced apart from the source doping region;
a second ion well of the second conductivity type encompassing the drain doping region;
a gate disposed on the gate dielectric layer and laterally extending onto the field oxide layer and the low dielectric constant material layer; and
a dielectric layer disposed on the gate, the gate dielectric layer, and the low dielectric constant material layer.

11. An ultra high voltage metal-oxide-semiconductor (MOS) transistor device, comprising:
a substrate of a first conductivity type;
a source doping region of a second conductivity type formed in the substrate;
a first doping region of the first conductivity type formed in the substrate and bordering upon the source doping region;
a first ion well of the first conductivity type encompassing the source doping region and the first doping region;
a gate dielectric layer formed on the source doping region and on the first ion well;
a shallow trench isolation region filled with a porous oxide material connected with the gate dielectric layer and formed on a semiconductor region;
a drain doping region of the second conductivity type formed at one side of the field oxide layer and being spaced apart from the source doping region;
a second ion well of the second conductivity type encompassing the drain doping region;
a gate disposed on the gate dielectric layer and laterally extending onto the shallow trench isolation region; and
a dielectric layer disposed on the gate, the gate dielectric layer, and the shallow trench isolation region.

12. A method of manufacturing an ultra high voltage MOS transistor device, comprising:
providing a substrate of a first conductivity type;
forming a first ion well of the first conductivity type and a second ion well of the second conductivity type;
forming a first doping region of the first conductivity type in the first ion well;
forming a source doping region of a second conductivity type and a drain doping region of the second conductivity type in the first ion well and the second ion well, respectively, wherein the source doping region borders upon the first doping region, such that the first ion well encompasses the source doping region and the first doping region;
forming a gate dielectric layer on the source doping region and on the first ion well;
forming a first dielectric layer connected with the gate dielectric layer on a semiconductor region, wherein the drain doping region is spaced apart from the source doping region with the first dielectric layer therebetween;
forming a gate on the gate dielectric layer to laterally extend onto the first dielectric layer;
removing a part of the first dielectric layer under an edge of the gate to form an opening; and
forming a second dielectric layer disposed on the gate, the gate dielectric layer, and the first dielectric layer, such that a void is formed in situ of the opening.

13. The method according to claim 12, wherein, the step of forming a first dielectric layer comprises forming a field oxide layer.

14. The method according to claim 12, wherein the step of forming the first dielectric layer comprises forming a field oxide layer connected with the gate dielectric layer on the semiconductor region and a third dielectric layer covering the field oxide layer; and the step of removing a part of the first dielectric layer under an edge of the gate comprises removing a part of the third dielectric layer under an edge of the gate to form the opening.

15. The method according to claim 12, wherein the step of forming a first dielectric layer comprises forming a field oxide layer connected with the gate dielectric layer on the semiconductor region and a third dielectric layer on the field oxide layer; and the step of removing a part of the first dielectric layer under an edge of the gate comprises removing a part of the third dielectric layer and a part of the field oxide layer together under an edge of the gate to form the opening.

16. The method according to claim 12, after forming the opening, further comprising filling the opening with a low dielectric constant material.

17. The method according to claim 12, wherein the step of forming the first dielectric layer comprises forming a shallow trench isolation region.

18. The method according to claim 12, wherein the step of forming the first dielectric layer comprises forming a shallow trench isolation region connected with the gate dielectric layer on the semiconductor region and a third dielectric layer on the shallow trench isolation region; and the step of removing a part of the first dielectric layer under an edge of the gate comprises removing a part of the third dielectric layer under an edge of the gate to form an opening.

19. The method according to claim 12, wherein the step of forming the first dielectric layer comprises forming a shallow trench isolation region connected with the gate dielectric layer on the semiconductor region and a third dielectric layer on the shallow trench isolation region; and the step of removing a part of the first dielectric layer under an edge of the gate comprises removing a part of the third dielectric layer and a part of the shallow trench isolation region together under an edge of the gate to form the opening.

20. A method of manufacturing an ultra high voltage MOS transistor device, comprising:
providing a substrate of a first conductivity type;
forming a first ion well of the first conductivity type and a second ion well of the second conductivity type;
forming a first doping region of the first conductivity type in the first ion well;
forming a source doping region of a second conductivity type and a drain doping region of the second conductivity type in the first ion well and the second ion well, respectively, wherein the source doping region borders upon the first doping region, such that the first ion well encompasses the source doping region and the first doping region;
forming a gate dielectric layer on the source doping region and on the first ion well;
forming a field oxide layer on a semiconductor region, forming a low dielectric constant material layer on the field oxide layer, wherein the drain doping region is spaced apart from the source doping region with the field oxide layer therebetween;
forming a gate on the gate dielectric layer to laterally extend onto the low dielectric constant material layer; and
forming a dielectric layer disposed on the gate, the gate dielectric layer, and the low dielectric constant material layer.

21. A method of manufacturing an ultra high voltage MOS transistor device, comprising:
providing a substrate of a first conductivity type;
forming a first ion well of the first conductivity type and a second ion well of the second conductivity type;
forming a first doping region of the first conductivity type formed in the first ion well;
forming a source doping region of a second conductivity type and a drain doping region of the second conductivity type in the first ion well and the second ion well, respectively, wherein the source doping region borders upon the first doping region, such that the first ion well encompasses the source doping region and the first doping region;
forming a gate dielectric layer on the source doping region and on the first ion well;
forming a shallow trench isolation region connected with the gate dielectric layer on a semiconductor region on a semiconductor region, wherein the shallow trench isolation region is filled with a porous oxide material and the drain doping region is spaced apart from the source doping region with the shallow trench isolation region therebetween;
forming a gate on the gate dielectric layer to laterally extend onto the shallow trench isolation region; and
forming a second dielectric layer disposed on the gate, the gate dielectric layer, and the shallow trench isolation region.

22. An ultra high voltage metal-oxide-semiconductor (MOS) transistor device, comprising:
a semiconductor substrate;
at least one doping region in the semiconductor substrate;
a gate on the semiconductor substrate;
a first dielectric layer between the gate and the doping region for isolation, wherein the gate laterally extends onto the first dielectric layer and the first dielectric layer has at least one void under an edge of the gate; and
a second dielectric layer disposed on the gate, the doping region, and the first dielectric layer, wherein the void is retained.

23. The ultra high voltage MOS transistor device according to claim 22, further comprising a gate dielectric layer between the gate and the semiconductor substrate.

24. The ultra high voltage MOS transistor device according to claim 22, wherein the doping region comprises a source or drain structure.

25. The ultra high voltage MOS transistor device according to claim 22, wherein the first dielectric layer comprises a field oxide layer.

26. The ultra high voltage MOS transistor device according to claim 22, wherein the first dielectric layer comprises a field oxide layer and a third dielectric layer stacked on the field oxide layer; and the field oxide layer comprises the void.

27. The ultra high voltage MOS transistor device according to claim 22, wherein the first dielectric layer comprises a field oxide layer and a third dielectric layer stacked on the field oxide layer; and the field oxide layer and the third dielectric layer together comprise the void.

28. The ultra high voltage MOS transistor device according to claim 22, wherein the first dielectric layer comprises a shallow trench isolation region.

29. The ultra high voltage MOS transistor device according to claim 22, wherein the first dielectric layer comprises a shallow trench isolation region and a third dielectric layer stacked on the shallow trench isolation region; and the shallow trench isolation region comprises the void.

30. The ultra high voltage MOS transistor device according to claim 22, wherein the first dielectric layer comprises a shallow trench isolation region and a third dielectric layer stacked on the shallow trench isolation region; and the shallow trench isolation region and the third dielectric layer together comprise the void.

31. The ultra high voltage MOS transistor device according to claim 22, wherein the void is filled with a low dielectric constant material.

32. The ultra high voltage MOS transistor device according to claim 22, comprising two doping regions having a source structure and a drain structure disposed at two ends of the gate, respectively.

33. The ultra high voltage MOS transistor device according to claim 32, wherein the first dielectric layer comprises the void under the edge of the gate at the end toward the drain structure or the source structure.

34. The ultra high voltage MOS transistor device according to claim 32, wherein the first dielectric layer comprises the void under each edge of the gate at the two ends toward the drain structure and the source structure, respectively.

35. An ultra high voltage metal-oxide-semiconductor (MOS) transistor device, comprising:
a semiconductor substrate;
at least one doping region in the semiconductor substrate;
a gate on the semiconductor substrate; and
a first dielectric layer between the gate and the doping region for isolation, wherein the gate laterally extends onto the first dielectric layer and the first dielectric layer comprises a porous oxide material.

36. An ultra high voltage metal-oxide-semiconductor (MOS) transistor device, comprising:
a semiconductor substrate;
at least one doping region in the semiconductor substrate;
a gate on the semiconductor substrate;
a first dielectric layer between the gate and the doping region for isolation, wherein the gate laterally extends onto the first dielectric layer and the first dielectric layer has at least one void under an edge of the gate; and
a second dielectric layer disposed on the gate, the doping region, and the first dielectric layer.
